(19) United States
(12) Patent Application Publication
(10) Pub. No.: US 2017/0127572 A1
(43) Pub. Date: May 4, 2017

(54) DATA CENTER COOLING SYSTEM

(71) Applicant: HON HAI PRECISION INDUSTRY CO., LTD., New Taipei (TW)

(72) Inventors: TZE-CHERN MAO, New Taipei (TW); CHAO-KE WEI, New Taipei (TW); YAO-TING CHANG, New Taipei (TW); HUNG-CHOU CHAN, New Taipei (TW); YEN-CHUN FU, New Taipei (TW); CHIH-HUNG CHANG, New Taipei (TW)

(21) Appl. No.: 14/976,159

(22) Filed: Dec. 21, 2015

(30) Foreign Application Priority Data
Oct. 30, 2015 (CN) 201510718863.7

(51) Int. Cl. H05K 7/20; E04H 5/00; E04D 11/00; F25B 19/00

(52) U.S. Cl. CPC H05K 7/20736; F25B 19/00; H05K 7/208; E04H 5/00; E04D 11/002; E04H 2005/005

(57) ABSTRACT

A data center cooling system includes a housing and a number of container data centers. The housing includes an enclosure and a roof. The enclosure defines at least one first air inlet. The roof is attached to the top of the enclosure and defines an air vent. The housing defines a vertical exhaust channel and a plurality of receiving spaces within the enclosure. The exhaust channel communicates with the air inlet. The receiving spaces communicate with the exhaust channel and the air inlet. The container data centers are received in the receiving spaces. A gap is formed between the container data center and the receiving space to allow the air from the first air inlet to flow through the exhaust channel through the gap to expel hot air surrounding the container data centers out of the air vent of the exhaust channel.

### CROSS-REFERENCE TO RELATED APPLICATIONS

This application claims priority to Chinese Patent Application No. 201510718863.7, filed on Oct. 30, 2015, the contents of which are incorporated by reference herein.

### FIELD

The subject matter herein relates to a data center cooling system.

### BACKGROUND

Container data centers generate a lot of heat during operation. The container data center is generally contained in a housing. A number of air conditioning devices are arranged in the housing to lower the temperature of the container data enter.

### BRIEF DESCRIPTION OF THE DRAWINGS

Implementations of the present technology will now be described, by way of example only, with reference to the attached figures.

FIG. 1 is a schematic view of a data center cooling system.

FIG. 2 is a cross-sectional view taken along the line of FIG. 1.

FIG. 3 is a cross-sectional view taken along the line II-II of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

The term “comprising” means “including, but not necessarily limited to”; it specifically indicates open-ended inclusion or membership in a so-described combination, group, series, and the like.

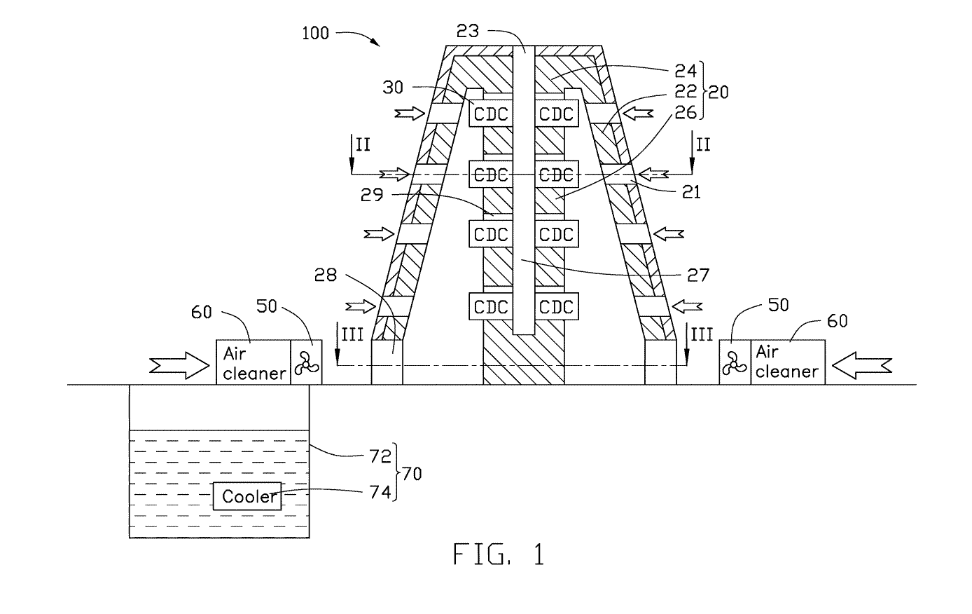

FIG. 1 illustrates a data center cooling system 100 according to an exemplary embodiment. In at least one embodiment, the data center cooling system 100 is formed from the earth and ground. The data center cooling system 100 includes a housing 20, a number of container data centers (CDC) 30 and a vegetation piece 40. The container data centers 30 are positioned in the housing 20. The vegetation piece 40 is covering the housing 20. Thus, the data center cooling system 100 joins well with the surroundings.

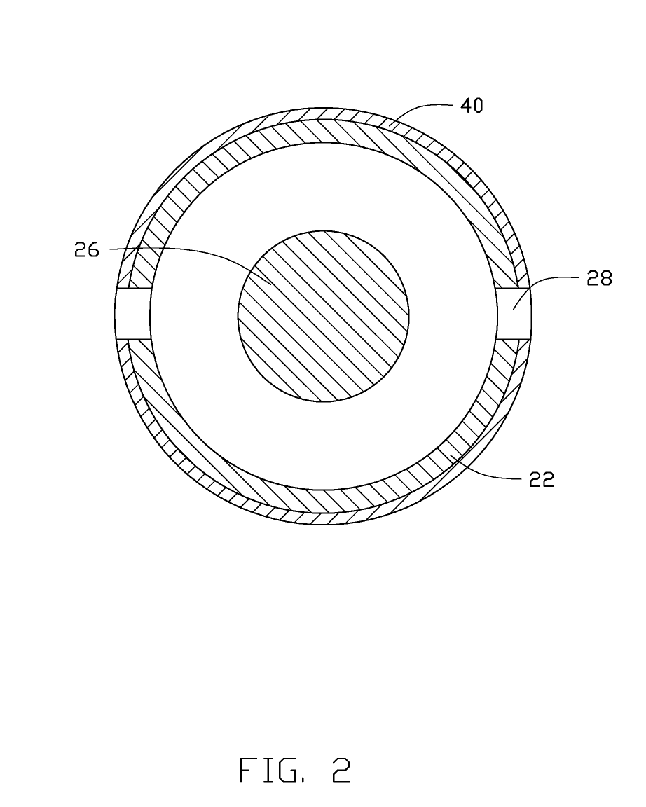

The housing 20 includes an enclosure 22, a roof 24 and a support pillar 26. The support pillar 26 is within the enclosure 22 and is attached to the roof 24. The support pillar 26 and the roof 24 are formed to be one piece. At least one first air inlet 28 is defined at the bottom of the enclosure 22. FIG. 2 illustrates two first air inlets 28 are defined at the bottom of the enclosure 22. The data center cooling system 100 further includes at least one fan 50. The fan 50 is near the first air inlet 28. The fan 50 draws air from outside the enclosure 22 into the enclosure 22.

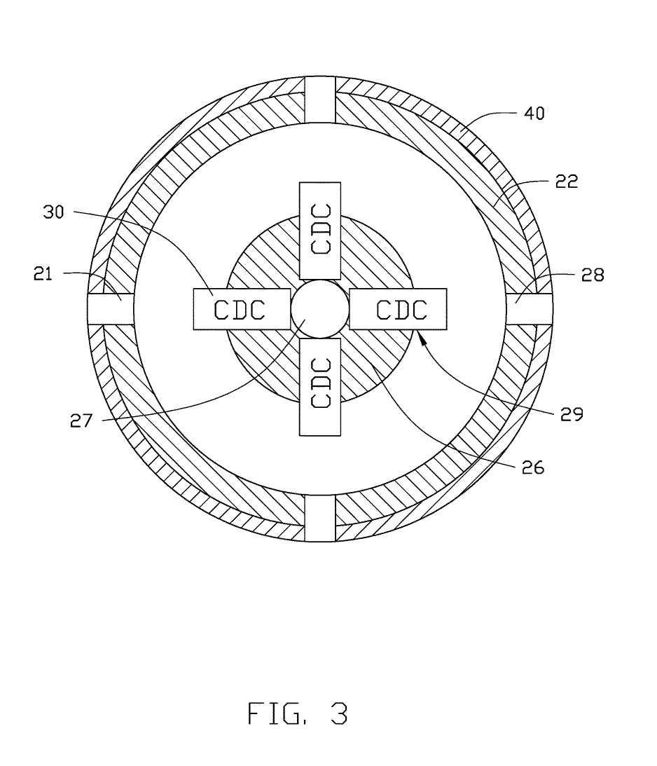

The roof 24 is attached to the top of the enclosure 22. An air vent 23 is defined in the roof 24 at a center. An exhaust channel 27 is defined in the support pillar 26 along the longitudinal direction. The exhaust channel 27 is in communication with the air vent 23 and faces the air vent 23. A number of rows of receiving spaces 29 are further defined in the supporting pillar 26 communicating with the exhaust channel 27. The number of rows of receiving spaces 29 surrounds the exhaust channel 27. FIG. 3 illustrates four rows of receiving spaces 29 are defined in the supporting pillar 26. Each row of receiving spaces 29 includes a number of receiving spaces 29 along the longitudinal direction of the support pillar 26. Each receiving space 29 is adjacent to the exhaust air channel 27 and communicates with the first air inlet 28.

The container data centers 30 are received in the receiving spaces 29. The container data centers 30 and the supporting pillar 26 surround the exhaust channel 27 to form a chimney. A gap (not labeled) is defined between the container data center 30 and the receiving space 29. Thus, air from the first air inlet 28 can flow to the exhaust channel 27 through the gap. Because the chimney effect of the exhaust channel 27, hot air formed by heat generated by the container data center 30 can be expelled out of the air vent 23.

The enclosure 22 further defines a number of second air inlets 21. The second air inlets 21 face the receiving spaces 29. Airflow passes through the second air inlet 21 to drive hot air formed by the heat generated by the container data center 30 to the exhaust channel 27. The chimney effect of the exhaust channel 27 exhausts hot air out of the air vent 23.

The vegetation piece 40 covers the enclosure 22 and the roof 24. The housing 20 is positioned at hilly terrain. The housing 20 is made of soil. Thus, the housing 20 joins well with the surroundings.

The data center cooling system 100 further includes at least one air cleaner 60 and at least one air cooling apparatus 70. The air cleaner 60 and the air cooling apparatus 70 are positioned near the first air inlet 28. The air cleaner 60 purifies the air. The air cooling apparatus 70 cools the air outside the enclosure 22. The air cooling apparatus 70 includes a pool 72 and a cooler 74. The cooler is positioned at the pool 72 and is configured to cool the water in the pool 72. The air near the pool 72 can be cooled during evaporation of the water.

The embodiments shown and described above are only examples. Even though numerous characteristics and advantages of the present technology have been set forth in the foregoing description, together with details of the structure and function of the present disclosure, the disclosure is illustrative only, and changes may be made in the details, including in matters of shape, size and arrangement of the parts within the principles of the present disclosure up to, and including, the full extent established by the broad general meaning of the terms used in the claims.

What is claimed is:

1. A data center cooling system comprising:
a housing comprising:
an enclosure having at least one first air inlet; and
a roof attached to the top of the enclosure and having an air vent;
a plurality of container data centers;
wherein the housing has a vertical exhaust channel and a plurality of receiving spaces within the enclosure, the exhaust channel communicates with the air inlet, the receiving spaces communicate with the exhaust channel and the air inlet, the container data centers are received in the receiving spaces, a gap is formed between the container data center and the receiving space to allow the air from the first air inlet flows to the exhaust channel through the gap to expel hot air formed by heat generated by the container data centers out of the air vent in chimney effect of the exhaust channel.

2. The data center cooling system as claimed in claim 1, further comprising:
at least one fan near the first air inlet, the fan configured to disperse air outside the enclosure into the enclosure.

3. The data center cooling system as claimed in claim 1, wherein the enclosure further defines a plurality of second air inlets, the second air inlets face the receiving spaces.

4. The data center cooling system as claimed in claim 1, further comprising:
a vegetation piece covering the enclosure and the roof.

5. The data center cooling system as claimed in claim 1, wherein the housing further comprises a supporting pillar, the supporting pillar is within the enclosure and is attached to the roof, the supporting pillar defines the exhaust channel and the receiving spaces.

6. The data center cooling system as claimed in claim 5, wherein the receiving spaces are formed four rows and surround the exhaust channel.

7. The data center cooling system as claimed in claim 1, further comprising:
at least one air cleaner near the first air inlet, the air cleaner configured to purify the air.

8. The data center cooling system as claimed in claim 1, further comprising:
an air cooling apparatus configured to cools the air outside the enclosure.

9. The data center cooling system as claimed in claim 8, wherein the air cooling apparatus comprises a pool, the air near the pool is cooled during evaporation of the water in the pool.

10. The data center cooling system as claimed in claim 9, wherein the air cooling apparatus further comprises a cooler, the cooler is positioned at the pool and is configured to cool the water in the pool.

11. A data center cooling system comprising:
a housing comprising:
an enclosure defining at least one first air inlet; and
a roof attached to the top of the enclosure and defining an air vent; and
a supporting pillar attached to the roof and defining an exhaust channel along the longitudinal direction of the supporting pillar and communicating with the air vent, the supporting pillar further defining a plurality of receiving spaces communicating with the exhaust channel and the first air inlet;
a plurality of container data centers received in the receiving spaces, a gap formed between the container data center and the receiving space to allow the air from the first air inlet flows to the exhaust channel through the gap to expel hot air formed by heat generated by the container data centers out of the air vent in chimney effect of the exhaust channel.

12. The data center cooling system as claimed in claim 11, further comprising:
at least one fan near the first air inlet, the fan configured to disperse air outside the enclosure into the enclosure.

13. The data center cooling system as claimed in claim 11, wherein the enclosure further defines a plurality of second air inlets, the second air inlets face the receiving spaces.

14. The data center cooling system as claimed in claim 11, further comprising:
a vegetation piece covering the enclosure and the roof.

15. The data center cooling system as claimed in claim 11, wherein the receiving spaces are formed four rows and surround the exhaust channel.

16. The data center cooling system as claimed in claim 11, further comprising:
at least one air cleaner near the first air inlet, the air cleaner configured to purify the air.

17. The data center cooling system as claimed in claim 11, further comprising:
an air cooling apparatus configured to cools the air outside the enclosure.

18. The data center cooling system as claimed in claim 17, wherein the air cooling apparatus comprises a pool, the air near the pool is cooled during evaporation of the water in the pool.
